(19) United States
(12) Patent Application Publication
(10) Pub. No.: US 2019/0330730 A1
(43) Pub. Date: Oct. 31, 2019

(54) SENSOR IN THE FIELD OF PROCESS AUTOMATION AND ITS MANUFACTURE

(71) Applicant: Endress+Hauser Conducta GmbH+Co. KG, Gerlingen (DE)

(72) Inventor: Ingrid Wunderlich, Radebeul (DE)

(21) Appl. No.: 16/395,433

(22) Filed: Apr. 26, 2019

(30) Foreign Application Priority Data
Apr. 27, 2018 (DE) 10 2018 110 189.9

(51) Int. Cl. C23C 14/06; C23C 16/448; G01L 1/00

(52) U.S. Cl. CPC C23C 14/0605; G01L 1/005; C23C 16/4485

(57) ABSTRACT

The present disclosure discloses a sensor in the field of process automation for detecting a measurand of a medium, the sensor including at least one metallic section including a coating with a diamond-like carbon layer. The present disclosure also discloses a method for producing the same.

### CROSS-REFERENCE TO RELATED APPLICATION

The present application is related to and claims the priority benefit of German Patent Application No. 10 2018 110 189.9, filed on Apr. 27, 2018, the entire contents of which are incorporated herein by reference.

### TECHNICAL FIELD

The present disclosure relates to a process automation technology sensor for detecting a measurand of a medium. The present disclosure also relates to the manufacture thereof.

### BACKGROUND

Sensors for analytical measuring technology are used in a wide variety of media, in particular, liquids. In many embodiments, steel parts, in combination with other materials, are used in contact with media.

This can lead to problems such as corrosion.

### SUMMARY

The aim of the present disclosure is to overcome these problems.

This is achieved by a sensor comprising: at least one metallic, including, at least partially, a coating with a diamond-like carbon layer.

The English term for “diamantähnliche Kohlenstoffschicht” is “diamond-like carbon” layer, or DLC.

The coating improves, for example, the gliding properties, so that less medium remains adhering to the sensor.

Furthermore, the formation of air bubbles is reduced or prevented.

In one embodiment, the coating can also be applied completely around the metallic section.

The metallic section is a solid body, a hollow body, or a metallic coating on a base body.

In one embodiment, the metallic section includes a medium-contacting side, and the coating is arranged on the medium-contacting side.

In one embodiment, the metallic section with a further section of the sensor forms a contact section. The further section may be another metal, a ceramic, or a plastic material.

The targeted use of such a coating on medium-contacting contact surfaces of a sensor or a medium-contacting assembly represents a solution to the problem of crevice corrosion. Compared with other known coatings, the coating exhibits extremely good adhesion and practically no defects.

In one embodiment, the metallic section includes a stainless steel.

In one embodiment, the metallic section with the coating with a diamond-like structure includes an adhesive layer. A layer structure of metal-coating adhesive thus forms. The coating with the diamond-like carbon layer improves the adhesion properties of the adhesive on the metal.

In one embodiment, the metallic section is overmolded with a plastic. A layer structure of metal-coating plastic thus forms.

In one embodiment, carbon is the predominant constituent in the diamond-like carbon layer.

In one embodiment, the diamond-like carbon layer comprises a mixture of sp3- and sp2-hybridized carbon and an amorphous structure.

In one embodiment, the diamond-like carbon layer comprises impurity atoms, such as, hydrogen, silicon, or fluorine. This targeted introduction of further constituents into the diamond-like carbon layer allows the spectrum of properties to be expanded. This includes, for example, the increase in hydrophobicity (reduction in the water wettability) or, alternatively, the increase in wettability with water (hydrophilicity), depending upon the impurity atom.

The aim is further achieved by a method comprising the step of coating at least one metallic layer with a diamond-like carbon layer.

In one embodiment, the method comprises coating a medium-contacting layer with a diamond-like carbon layer.

In one embodiment, the coating is applied using PVD or CVD methods.

The term, chemical vapor deposition (German, “chemische Gasphasenabscheidung”), or CVD, signifies a group of coating processes, which can be used, inter alia, in the production of microelectronic devices. A solid component is deposited on the heated surface of a substrate due to a chemical reaction from the gas phase. A prerequisite for this is that volatile compounds of the layer components exist which deposit the solid layer at a certain reaction temperature. The chemical vapor deposition process includes at least one reaction on the surface of the workpiece to be coated. At least one gaseous starting compound (educt), and at least two reaction products, at least one of which is in the solid phase, may be involved in this reaction. In order to promote, with respect to competing gas-phase reactions, those reactions on the surface, and thus to avoid the formation of solid particles, chemical vapor deposition processes are usually operated at reduced pressure (typically: 1-1,000 Pa). A particular property of the method is conformal layer deposition. In contrast to physical methods, chemical vapor deposition also enables the coating of complex, three-dimensionally-shaped surfaces. Thus, for example, the finest depressions in wafers or even hollow bodies can be evenly coated on their insides. Precise deposition can also be achieved with the aid of focused electron beams or ion beams. The charged electrons or ions cause the substances dissolved in the gas to deposit at the irradiated sites. Such electron beams can be generated, for example, with a synchrotron. The ion beams can be generated with a FIB device. These also enable selective, gas-assisted ion beam etching.

In one embodiment, the coating is applied using PECVD methods.

Plasma-enhanced chemical vapor deposition (PECVD) (also PACVD, “plasma-assisted chemical vapor deposition”; in German, “plasmaunterstützte chemische Gasphasenabscheidung”) is a special form of chemical vapor deposition (CVD) in which chemical deposition is assisted by a plasma. The plasma can burn directly in the substrate to be coated (direct plasma method) or in a separate chamber (remote plasma method). In CVD, the dissociation (rupture) of the molecules of the reaction gas is effected by the external supply of heat and the released energy of the subsequent chemical reactions, whereas in PECVD, this task is taken over by accelerated electrons in the plasma. In addition to the radicals formed in this way, ions are also generated in a plasma, which, together with the radicals, effect the layer deposition on the substrate. The gas temperature in the plasma generally increases by only a few hundred degrees Celsius, whereby, in contrast to CVD, even temperature-sensitive materials can be coated. In the direct plasma method, a strong electric field is applied between the substrate to be coated and a counter electrode, through which a plasma is ignited. In the remote plasma method, the plasma is arranged such that it has no direct contact with the substrate. This provides advantages with regard to the selective excitation of individual components of a process gas mixture and reduces the possibility of plasma damage to the substrate surface by the ions. Disadvantages are, possibly, the loss of radicals on the segment between remote plasma and substrate, and the possibility of gas phase reactions before the reactive gas molecules have reached the substrate surface.

In one embodiment, the plasma excitation of the gas phase in the PECVD method takes place by coupling pulsed direct voltage, or medium-frequency or high-frequency power.

In one embodiment, the process temperature is less than 150° C.

The term, physical vapor deposition (PVD for short; “physikalische Gasphasenabscheidung” or, rarely, also “physikalische Dampfphasenabscheidung” in German), refers to a group of vacuum-based coating methods or thin-film technologies. Unlike with chemical vapor deposition processes, with the aid of physical processes, the starting material is transferred into the gas phase. The gaseous material is then guided to the substrate to be coated, where it condenses and forms the target layer.

In this case, the material to be deposited is present in solid form in the mostly evacuated coating chamber. The material designated as the target is evaporated by bombardment with laser beams, magnetically-deflected ions or electrons, and by arc discharge. How high the proportion of atoms, ions, or clusters in the vapor might be is different from process to process. The evaporated material moves through the chamber either ballistically or guided by electric fields and impinges on the parts to be coated, where layer formation occurs. In order that the vapor particles also reach the components and not be lost by scattering on the gas particles, it is preferable to work under reduced pressure. Typical working pressures range from 10-4 Pa to about 10 Pa. Since the vapor particles spread in a straight line, surfaces which are not visible from the location of the vapor source are coated at a lower coating rate. If all surfaces are to be coated as homogeneously as possible, the parts must be moved in a suitable manner during the coating. This is usually effected through rotation of the substrate. If the vapor particles now encounter the substrate, they begin to deposit on the surface by condensation. The particles do not remain in the place and position at which they strike the substrate, but, rather, move along the surface (surface diffusion), each according to how high its energy is, in order to find an energetically more favorable place. These are sites on the crystal surface with as many neighbors as possible (higher binding energy). In order to increase the coating rate and layer homogeneity, the layout can be easily varied depending upon the coating process and the material to be deposited. For example, in thermal evaporation, a negative voltage is applied to the parts to be evaporated (bias voltage). This accelerates the positively-charged vapor particles or metal ions.

In one embodiment, the method further includes the step of applying an adhesive layer to the coating with a diamond-like carbon layer.

### BRIEF DESCRIPTION OF THE DRAWINGS

This will be explained in more detail with reference to the following figures.

FIG. 1 shows an exemplary embodiment of a sensor.

FIG. 2 shows a layer structure.

### DETAILED DESCRIPTION

A sensor 1 comprises at least one sensor element for detecting a measurand of process automation. The sensor 1 is then, for example, a pH sensor, also referred to as an ISFET (generally, an ion-selective sensor), a sensor for measurement of the redox potential, from the absorption of electromagnetic waves in the medium, e.g., with wavelengths in the UV, IR, and/or visible range, of the oxygen, of the conductivity, of the turbidity, of the concentration of non-metallic materials, or of the temperature, along with the respectively corresponding measurand.

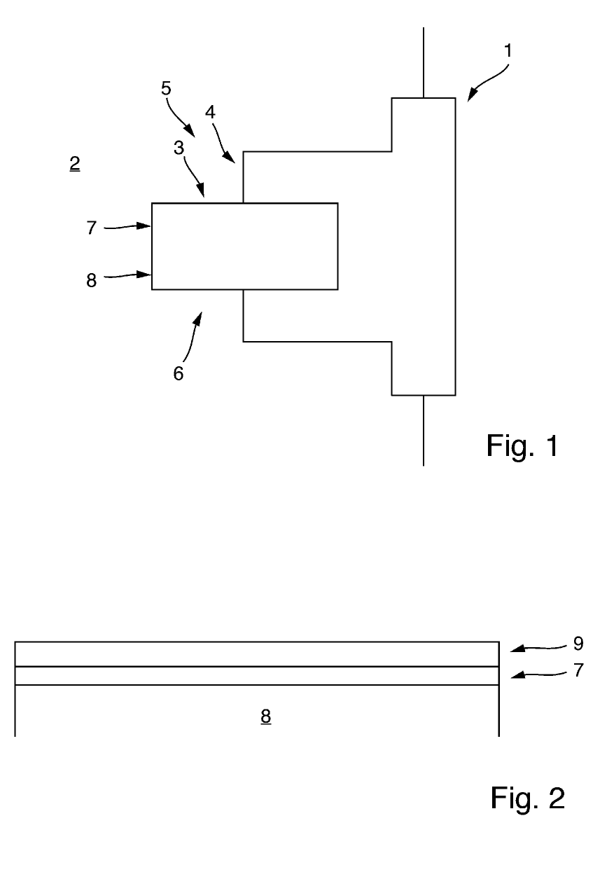

FIG. 1 shows a sensor 1 comprising at least one metallic section 8.

The sensor 1 is immersed at least in sections in the medium 2 to be measured. This results in a medium-contacting section 6. The metallic section 8 can also form the medium-contacting section 6, at least in sections. The medium-contacting section 6 of the sensor 1 comprises at least two different regions 3 and 4. These can be made of different materials. The regions 3 and 4 form a contact section 5.

Illustrated in FIG. 1 is the region 3 of the process connection of the sensor 1, which region 3 is used for connecting the sensor 1 to the medium 2. However, the region 3 can also be another section of the sensor 1. At least one of the materials of the regions 3 or 4 is made of a material susceptible to corrosion. This is particularly the case when the medium 2 to be measured contains a corrosive element, such as, for example, oxygen. The risk of corrosion, particularly crevice corrosion, is high, in particular, at the transition point between the different materials.

A coating with a diamond-like carbon layer 7 is applied to the metallic section 8, such as the medium-contacting section 6 of the sensor 1, by means of a CVD process, such as, for example, a PECVD process. The coating is up to a few micrometers thick. One embodiment comprises a layer thickness of less than 20 μm. Alternatively, for example, a PVD process may be used.

Coating the metallic section 8 with the diamond-like carbon layer 7 improves the gliding characteristics. This results in poorer adhesion of contamination, etc., to the sensor 1. If the diamond-like carbon layer 7 is applied to the medium-contacting section 6, corrosion may be avoided there.

In one embodiment (not shown), the metallic section 8 is overmolded by a plastic. The diamond-like carbon layer 7 on the metallic section 8 ensures better adhesion of the plastic.

In PECVD, chemical deposition is assisted by a plasma. The plasma can burn directly in the substrate to be coated (direct plasma method) or in a separate chamber (remote plasma method). Analogously to the classical CVD process, the PECVD process works only with gases. However, whereas the CVD method usually involves coating at temperatures of above 1,000° C., the plasma-assisted CVD method makes use of markedly lower temperatures in the range of 100-600° C. Here, temperatures below 150° C. are present. In this case, the plasma serves as a catalyst for the reaction or for the splitting of the reactive gases, such as in the deposition of the coating of diamond-like carbon by splitting C2H2 or CH4. Further gases used are Ar, H2, or O2.

The plasma excitation of the gas phase is effected by the coupling of pulsed direct voltage, medium-frequency (i.e., in the kHz range) power, or high-frequency (i.e., in the MHz range) power. The power density is about 0.1 to 0.5 W/cm (on the substrate, i.e., in the area of the coating).

The process pressure is about 1 to 100 Pa.

The diamond-like carbon, or DLC, layer 7 (German: ““diamantähnliche Kohlenstoffschicht”) consists of a mixture of sp3- and sp2-hybridized carbon and has an amorphous structure. Impurity atoms such as hydrogen, silicon, or fluorine may also be incorporated into this diamond-like carbon layer 7. This targeted introduction of further constituents into the diamond-like carbon layer 7 allows the spectrum of properties to be expanded. This includes, for example, the increase in hydrophobicity (reduction in the water wettability) or, alternatively, the increase in wettability with water (hydrophilicity), depending upon the impurity atom. This is referred to as a modified diamond-like carbon layer 7.

Diamond-like carbon layers 7 can be applied to a multiplicity of different materials, provided that they are compatible with the vacuum required for the production of the layer 7. As a result of the method, all components to be coated should be electrically conductive. The bombardment of the surfaces with energetic plasma ions required for constructing the diamond-like carbon layer 7 can thus be ensured. There is an exception for thin insulating layers (i.e., the maximum thickness is only a few millimeters), which can also be coated with this method.

FIG. 2 shows a layer structure on the sensor 1. A diamond-like carbon layer 7 is first applied to the metallic section 8 of the sensor 1. An adhesive layer 9 is then applied. The diamond-like carbon layer 7 results in better adhesion of the adhesive 9. This results in an improvement of a firmly-bonded connection.

A similar layer structure results when the metallic section 8 with the diamond-like carbon layer 7 is overmolded with a plastic.

1. A sensor in the field of process automation for detecting a measurand of a medium, comprising:
at least one metallic section of the sensor at least partially including a coating with a diamond-like carbon layer.

2. The sensor of claim 1, wherein the metallic section includes a medium-contacting side, and the coating is arranged on the medium-contacting side.

3. The sensor of claim 1, wherein the metallic section and a further section of the sensor form a contact section.

4. The sensor of claim 1, wherein the metallic section with the coating including the diamond-like carbon layer includes an adhesive layer.

5. The sensor of claim 1, wherein carbon is a predominant constituent in the diamond-like carbon layer.

6. The sensor of claim 1, wherein the diamond-like carbon layer includes a mixture of sp³- and sp²-hybridized carbon and includes an amorphous structure.

7. The sensor of claim 1, wherein the diamond-like carbon layer includes hydrogen, silicon, or fluorine.

8. A method for producing a sensor in the field of process automation for detecting a measurand of a medium, comprising a step of:
coating at least one metallic layer of the sensor with a diamond-like carbon layer.

9. The method of claim 8, wherein the coating is applied using a PVD method or a CVD method.

10. The method of claim 9, wherein the coating is applied using PECVD method.

11. The method of claim 10, wherein the plasma excitation of a gas phase in the PECVD method includes coupling pulsed direct voltage, or medium-frequency or high-frequency power.

12. The method of claim 8, further including applying an adhesive layer to the diamond-like carbon layer.

13. The method of claim 8, further including depositing the diamond-like carbon layer at a deposition temperature less than 150° C.
